(19) United States
(12) Patent Application Publication
(10) Pub. No.: US 2020/0321265 A1
(43) Pub. Date: Oct. 8, 2020

(54) HEAT SINK INCORPORATING MICROENCAPSULATED PHASE-CHANGE MATERIAL

(71) Applicant: RAYTHEON COMPANY, WALTHAM, MA (US)

(72) Inventors: PETER A. BELLUS, TUCSON, AZ (US); JAMES E. FAORO, TUCSON, AZ (US)

(21) Appl. No.: 16/373,928

(22) Filed: Apr. 3, 2019

(51) Int. Cl. H01L 23/427; H01L 23/373; F28F 3/04

(52) U.S. Cl. CPC H01L 23/4275; F28F 3/046; H01L 23/373

(57) ABSTRACT

A heat sink includes a plurality of encapsulated spheres dispersed throughout the heat sink. Each encapsulated sphere includes a solid-to-liquid phase-change material surrounded by a metal shell.

### BACKGROUND

The present disclosure generally relates to heat sinks, and more specifically to heat sinks incorporating microencapsulated phase-change material.

Thermal transport limits the reliability and performance of electronic devices. In many advanced technologies, such as micro- and nano-electronics, optoelectronics, micro-electro-mechanical systems (MEMS), photovoltaic systems, and electrochemical batteries, size, weight, and power considerations drive the technology. As devices have become progressively smaller, more powerful, and more complex, they dissipate larger amounts of heat per unit area. Cooling systems, also referred to as heat sinks, are coupled to heat generating devices to aid in thermal transport to keep such devices from overheating.

Various materials have been used to cool electronic systems. For example, phase-change materials have been used to cool electronics that undergo short duration heating. The phase-change material absorbs heat by quickly undergoing a phase-change, usually melting, and then slowly releasing heat to the environment by recrystallizing after the heat impulse has passed. As such, phase-change materials can be considered as substances with a high heat of fusion that, by melting and solidifying at a certain temperature, can store and release large amounts of heat.

### SUMMARY

According to one or more embodiments of the present invention, a heat sink includes a plurality of encapsulated spheres dispersed throughout the heat sink. Each encapsulated sphere includes a solid-to-liquid phase-change material surrounded by a metal shell.

According to other embodiments of the present invention, a heat-absorbing structure includes a structural matrix including a first metal; a plurality of voids arranged in the structural matrix; and a phase-change material arranged in the plurality of voids. The phase-change material includes a second metal.

According to some embodiments of the present invention, a method of making a heat sink includes forming spheres of a phase-change material. The phase-change material includes a solid-to-liquid hase-change material. The method further includes adding the spheres to a metal solution to form metal encapsulated spheres within the metal solution. The metal encapsulated spheres include metal shells around the phase-change material. The method also includes using the metal solution including the metal encapsulated spheres to form the heat sink.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

For a more complete understanding of this disclosure, reference is now made to the following brief description, taken in connection with the accompanying drawings and detailed description, wherein like reference numerals represent like parts:

FIG. 1 illustrates an exploded view of an electronic device with a heat sink including a phase-change material;

FIG. 2 illustrates a heat sink including a phase-change material;

FIG. 3 illustrates a method of preparing an encapsulated phase-change materials according to embodiments of the present invention;

FIGS. 4A and 4B illustrate a method of electrodepositing the encapsulated phase-change materials to form a heat sink according to embodiments of the present invention, in which:

FIG. 4A illustrates the heat sink, subsequent to depositing the encapsulated phase-change materials on a substrate to form a coating; and

FIG. 4B illustrates the heat sink, subsequent to depositing a lid on the coating;

FIG. 5 illustrates an electroformed heat sink structure including the encapsulated phase-change materials according to embodiments of the present invention;

FIG. 6A illustrates a structure according to embodiments of the present invention; and

FIG. 6B illustrates an expanded view of a portion of the structure shown in FIG. 6A.

### DETAILED DESCRIPTION

Turning now to an overview of technologies that are more specifically relevant to aspects of the invention, a challenge of using conventional phase-change materials (e.g., paraffin) in heat sinks coupled to heat generating electronic devices is that they are not particularly thermally conductive. In computers, for example, heat sinks cool central processing units or graphics processors. Heat sinks are also coupled to high-power semiconductor devices, such as power transistors and optoelectronics (e.g., lasers and light emitting diodes (LEDs)), where the heat dissipation ability of the component itself is insufficient to moderate its temperature.

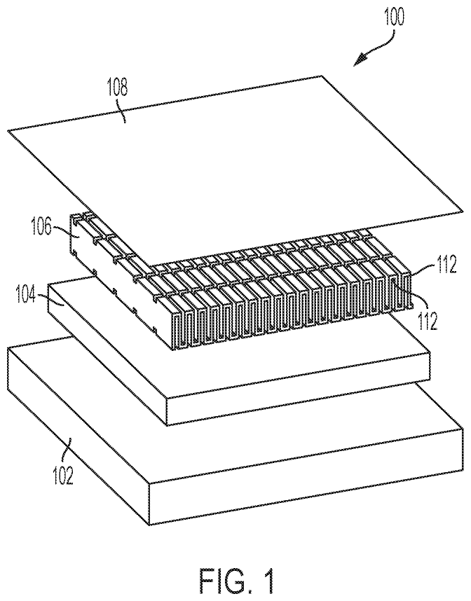

Various approaches are used increase the effective thermal conductivity of phase-change materials. FIG. 1, for example, illustrates an exploded view of an electronic device 100, which shows how a phase-change material 104 is conventionally used. The phase-change material 104 is arranged between a heat source 102 and a lid 108. The heat source 102 can be any type of heat source such as, for example, an integrated circuit. A metal fin structure 106 includes fins 112 that pass through the phase-change material 104 and contact the heat source 102 to provide a high surface area interface to the phase-change material 104. The metal fin structure 106 can be prefabricated with a liquid phase-change material embedded in the structure. Using high surface area fins increase the thermal conductivity into the phase-change material 104, as heat will travel up the high conductivity fins and then into the phase-change material 104. The high conductivity and large surface area of the fins increases the maximum power that can be applied to the heat source 102. Although the high surface area fins increase the thermal conductivity of the phase-change material, the entire electronic device 100, including a lid 108 arranged on the metal fin structure 106, must be welded together. However, since the phase-change materials are typically subject to degradation at the high temperatures used during metal welding, the welding must occur prior to filling, an opening must be left to allow filling the structure with phase-change material, and the opening must be sealed after filling to prevent leakage. Further, in a small electronics assembly, the parts to be welded will be small, requiring an intricate welding operation that is costly.

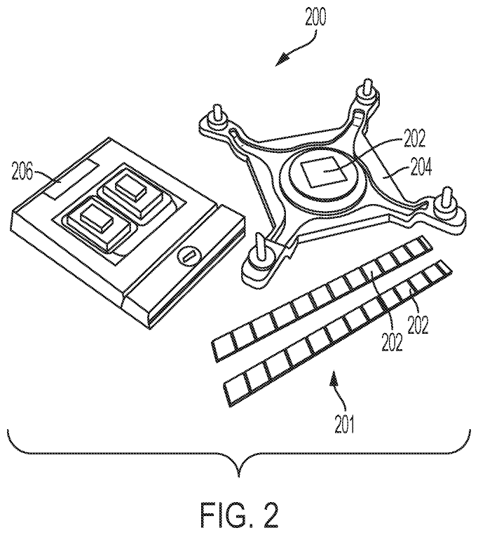

To minimize thermal resistance, conventional phase-change materials are also often applied as thin films between the part to be cooled and the heat sink. FIG. 2 illustrates an electronic device 200 with a heat sink 204 including a conventional phase-change material applied as a thin film 202, which is provided on strips 201. The thin film 202 will interface with the electronic part 206 to be cooled. However, these thin films may not effectively dissipate heat.

Solid-to-liquid phase-change materials are also challenging because, depending on the conditions, they can include material in liquid form. By the nature, phase-change materials must transition from one phase to another, typically solid to liquid, and absorb the heat of fusion during melting. However, when the phase-change material is in a liquid form, the material must be contained so that it does not leak out of the assembly. While fillers can be included in the phase-change materials so that the “liquid” phase is instead a “gel” phase, any filler used to form the gel will reduce the volume of the actual phase-change chemical. The amount of heat that can be absorbed is directly proportional to the amount of phase-change material at the interface, and such types of inert fillers necessarily displace part of the active phase-change material with an inert material. Further, such inert materials are typically not especially thermally conductive.

Turning now to an overview of the aspects of the invention, one or more embodiments of the invention address the above-described shortcomings of the prior art by providing methods and structures utilizing phase-change materials encapsulated in metal shells. The metal shells contain the phase-change materials and provide a thermally conductive path from the phase-change material contents to the environment. The metal shell encapsulated phase-change materials are electroplated onto an existing structure, as a layer or coating, to function as a heat sink. Electroforming also can be used to form any size or shaped stand-alone heat dissipating structure with the metal shell encapsulating phase-change materials.

The above-described aspects of the invention address the shortcomings of the prior art by providing methods and structures that efficiently transfer thermal energy from the heat source to the phase-change material, which is advantageous for absorbing pulsed heat from electronics. For example, when short duration heating is followed by long periods over which the heat can dissipate, the metal encapsulated phase-change materials will absorb the pulse energy, and, by virtue of the superior thermal conductivity, efficiently conduct heat to a heat sink to dissipate that heat over time. Also, in systems in which a large amount of heat needs to be absorbed over a short period of time, the metal encapsulated phase-change do not rely solely on thermal conductivity to remove heat, but absorb that heat in driving the change in phase of the phase-change heat absorber.

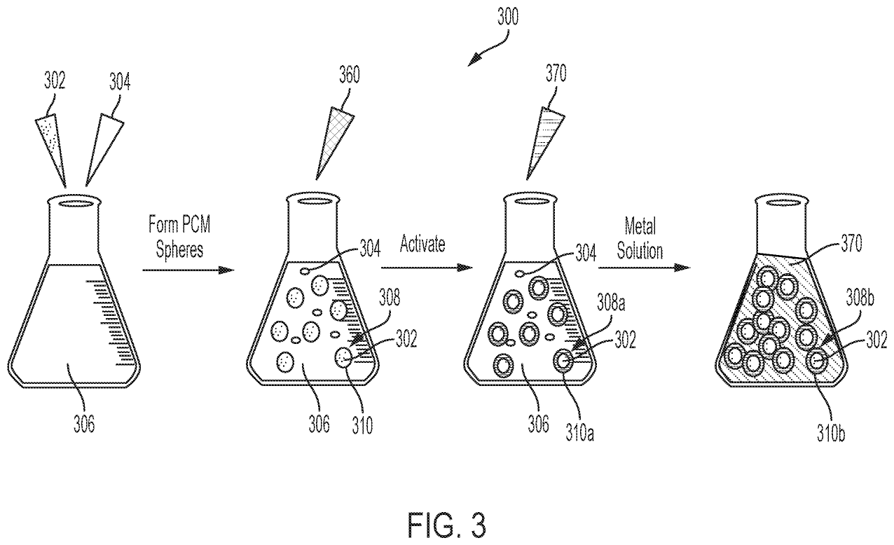

Turning now to a more detailed description of aspects of the present invention, FIG. 3 illustrates a method 300 of preparing an encapsulated phase-change material according to embodiments of the present invention. The phase-change material 302 is dispersed in water 306 (e.g., an aqueous solution) using a surfactant 304 and agitation control to form the desired sphere (e.g., microsphere) size.

The phase-change material 302 is a solid-to-liquid (also referred to as liquid-solid, solid-liquid, and liquid-to-solid) phase-change material. According to one or more embodiments of the present invention, the phase-change material 302 is a water insoluble phase-change material. Yet, according to other embodiments, the phase-change material 302 is a water-soluble phase-change salt. When water insoluble phase-change materials 302 are used, they can be plated with metal in an electroless plating process that is typically carried out in water. When a water-soluble phase-change salt is used, physical vapor deposition (PVD), for example, can be used. Non-limiting examples of phase-change materials 302 include paraffins, fatty acids, sugar alcohols, and combinations thereof.

Dispersion of the phase-change material 302 is conducted at a temperature above the melting temperature of the phase-change material. According to one or more embodiments of the present invention, the melting temperature of the phase-change material 302 is about −40° C. to about 2,000° C. According to other embodiments of the present invention, the melting temperature of the phase-change material 302 is about 60 to about 25° C. to about 225° C., or about 100° C. to about 150° C.

Non-limiting examples of surfactants 304 for dispersing the phase-change material 302 include cationic surfactants, such as cetyltrimethyl ammonium bromide (CTAB), anionic surfactants, such as sodium lauryl sulfate (SLS), nonionic surfactants, such as Triton X-100, PEG-600 or 1,4-butynediol, or any combination thereof.

Other compounds and materials that can be included with the phase-change material 302 and surfactant 304 in water 306 include, but are not limited to, complexing agents, such as nitrilotriacetic acid and ethylenediaminetetraacetic acid (EDTA); additives that improve surface finish, such as tetraethylammonium salts, or any combination thereof.

The phase-change material 302, surfactant 204, and other additional compounds are combined in the water 306 and stirred and/or agitated at a temperature above the melting temperature of the phase-change material 302 to form the desired sphere or droplet size. The type and concentration of the surfactant 304 and phase-change material 302, as well as agitation, is used to achieve the desired droplet or sphere size.

The temperature is then lowered below the solidification point of the phase-change material to form solid spheres 308 dispersed in water 306. The resulting spheres 308 include the phase-change material 302 inside a shell 310 of surfactant surrounding the phase-change material 302. In the molten phase, the phase-change material 302 is dispersed in solution. The surfactant 304 on the surface aids in keeping the liquid phase-change material 302 dispersed. The form of the phase-change liquid as dispersed is typically spherical droplets due to surface tension.

The solidification point of the phase-change material 302 is about −40° C. to about 2,000° C. according to some embodiments of the present invention. The solidification point of the phase-change material 302 is about 60° C. to about 125° C. according to other embodiments of the present invention.

The solid spheres 308 are then activated by adding a surface activator(s) 360 to the suspension of solid spheres 308. The surface activator 360 activates the surface shell 310 of the solid spheres 308 for metal shell formation, for example by electroless plating or electroforming. The activated spheres 308a include an activated shell 310a.

According to one or more embodiments of the present invention, the surface activator(s) 360 includes a metal chloride(s), e.g., tin chloride (SnCl2) or palladium chloride (PdCl2). Another non-limiting example of a surface activator 306 includes silver nitrate. A variety of proprietary activators can be used in electroless plating processes developed for plating various surfaces.

According to some embodiments of the present invention, tin chloride activator is added to the suspension, and the dispersed spheres are washed. Palladium chloride activator is then added, and the spheres are washed again before adding to a metal solution.

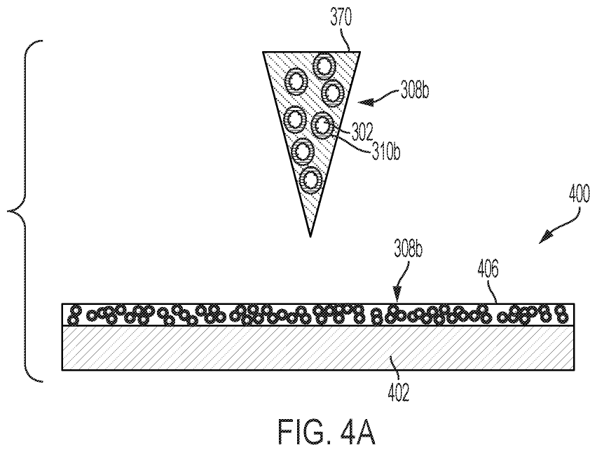

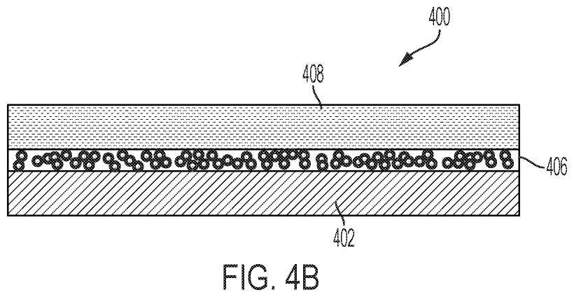

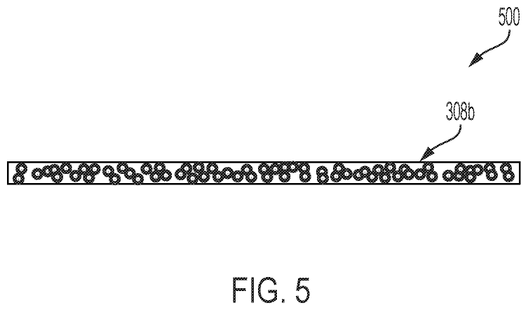

A metal solution 370 is added to the activated spheres 308a to form spheres 308b including the phase-change material 202 surrounded by a metal shell 310b. The spheres 308b will be present in a solution of the electroless metal plating solution 370. The metal solution 370 is an electroless plating solution that is used for electroless plating according to some embodiments of the present invention (see FIGS. 4A and 4B). The metal solution 370 is an electroforming solution that is used for electroforming according to other embodiments of the present invention (see FIG. 5). The electroplating or electroforming are conducted at a temperature below the solidification temperature of the phase-change material 302, which is provided above.

The metal solution 370, such as the electroless plating solution or electroforming solution, that forms the metal shell 310b around the spheres 308b can include any metal or metal alloys. According to one or more embodiments of the present invention, the metal is copper. Other non-limiting examples of metals include nickel, gold, iron, or any combination thereof.

The metal shell 310b around the spheres 308b result in metal spheres 308b (or microspheres) with a diameter of about 1 micrometer to about 200 micrometers according to some embodiments of the present invention. According to other embodiments of the present invention, the metal spheres 308b (or microspheres) have a diameter of about 10 micrometers to about 50 micrometers.

FIGS. 4A and 4B illustrate a method of electrodepositing the microencapsulated phase-change materials to form a heat sink 400 coupled to a surface of an electronic device according to embodiments of the present invention. Electroplating the microencapsulated phase-change materials allows an existing structure to have a heat storage structure added onto its existing form.

FIG. 4A illustrates the heat sink 400, subsequent to depositing the microencapsulated phase-change materials on a substrate 402 to form a phase-change material layer 406. The substrate 402 is a surface or part of a heat-generating device, such as an electronic device. The substrate 402 includes any types of materials, including, but not limited to, metals, glass, dielectric materials, and semiconductor materials. According to exemplary embodiments of the present invention, the substrate 402 is a thermal array on a printed wiring board.

The spheres 308b of phase-change material 302 in the metal solution 370 is plated by an electroless process to form a phase-change material layer 406 (or coating) with a thickness that can tailored to the type of substrate 402. The relative size and shape of the substrate 402 is shown for illustrative purposes only and is not intended to limit the size, shape, or dimensions of the substrate 402. The substrate 402 can have any size, shape, or dimensions.

According to some embodiments of the present invention, the thickness of the resulting phase-change material layer 406 is about 0.001 inch to about 0.25 inch. According to other embodiments of the present invention, the thickness of the phase-change material layer 406 is about 0.01 inch to about 0.10 inch.

FIG. 4B illustrates the heat sink 400, subsequent to depositing an optional lid 408 on the phase-change material layer 406. Because the phase-change material layer 406 forms a layer or coating that is directly plated onto the surface of the substrate 402, annealing does not need to be performed to couple the lid 408 to the phase-change material layer 408, in contrast to other processes that use phase-change materials in combination with high surface area fins (see FIG. 1). The lid 408 can be fabricated from a variety of materials, including but not limited to, Be—Cu alloys, Fe—Ni—Co alloys (e.g., Kovar), Cu—Mo—Cu alloys, Fe—Ni alloys (e.g., Alloy 42), or a combination thereof.

FIG. 5 illustrates a heat sink 500 including the microencapsulated phase-change materials as an electroformed structure according to embodiments of the present invention. Electroforming is a metal forming process that forms parts through electrodeposition on a model, known as a mandrel. Electroforming can be used to form a structure, having any size, shape, or dimensions. The electroformed structure can be a free-standing structure that incorporates the phase-change material throughout the entire structure, providing maximum heat storage.

The relative size and shape of the electroformed structure of the heat sink 500 is shown for illustrative purposes only and is not intended to limit the size, shape, or dimensions of the substrate 402. The heat sink 500 can have any size, shape, or dimensions.

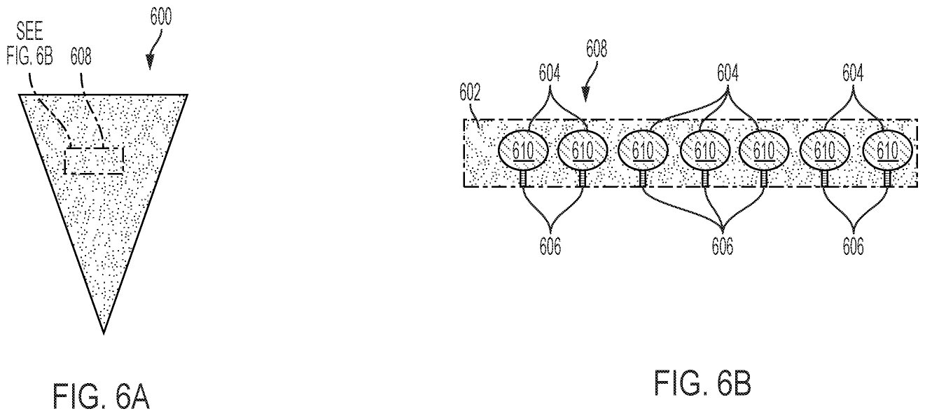

FIG. 6A illustrates a structure 600 according to embodiments of the present invention. The structure 600 is a heat-absorbing part or structure, for example, which can be part of a hypersonic vehicle, or any structure that can operate at high temperatures (e.g., 1,000° C.) and maintain strength. The structure 600 has any shape, size, or dimension, and the shape shown in FIG. 6A is only an example. Non-limiting examples of shapes for the structure 600 include cones, spheres, cubes, cylinders, cuboids, tetrahedrons, triangular prisms, square-based pyramids, or any combination thereof.

FIG. 6B is an expanded view of the area 608 of the structure 600. Area 608 shows the structure 600 includes a structural matrix 602 that includes one or more metals or metal alloys (also referred to herein as the first metal). The structural matrix 602 includes a metal or metal alloy that is highly resistant to oxidation and temperature. The structural matrix 602 includes void spaces 604 filled with a lower temperature melting metal 610 in the molten phase, which is a phase-change material. Non-limiting examples of metals and alloys for the structural matrix 602 include gallium, nickel, chromium, iron, molybdenum, niobium, tantalum, cobalt, manganese, copper, aluminum, titanium, or any combination thereof. Another non-limiting example of an alloy with a lower temperature melting metal 610 is Wood's metal. The metals and alloys can also include other non-metals, for example, silicon, carbon, phosphorus, boron, or a combination thereof. According to some embodiments of the present invention, the structural matrix 602 includes Iconel 718.

According to one or more embodiments of the present invention, the structure 600 is fabricated by three-dimensional printing with void spacing, and then introducing the lower temperature melting metal 610 (phase-change material) into the voids.

According to other embodiments of the present invention, the structure 600 is fabricated monolithically by cold spray, where a mixture of metal powders including the structural matrix 602 and lower temperature melting metal 610 are sprayed together to produce a cold-forged structure with internal voids filled with the lower temperature melting metal 610.

The lower temperature melting metal 610 (also referred to herein as the second metal) is embedded in the structural matrix 602 and absorbs large amounts of heat by first melting and then boiling. The lower temperature melting metal 610 functions as the phase-change material. Non-limiting examples of the lower temperature melting metal 610 that is the phase-change material are metals, such as aluminum or zinc, that melt at a much lower temperature than, for example, Inconel that would form the metal structure.

According to some embodiments of the present invention, the first metal of the structural matrix 602 has a melting temperature of about 80° C. to about 1500° C. Yet, according to other embodiments of the present invention, the second metal of the lower temperature melting metal 610 has a melting temperature of about 180° C. to about 700° C.

According to some embodiments of the present invention, the structure 600 includes, optionally, vents 606 that provide an escape path to the outside of the structure. The vents allow the boiled metal to escape as exhaust during the phase-change. The lower temperature melting metal 610 can continue to heat until they boil off through the vents 606, which removes more heat from the structure, with the latent heat effect being from a single phase-transition (e.g., melting and boiling).

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

While the preferred embodiments to the invention have been described, it will be understood that those skilled in the art, both now and in the future, may make various improvements and enhancements which fall within the scope of the claims which follow. These claims should be construed to maintain the proper protection for the invention first described.

What is claimed is:

1. A heat sink comprising:
a plurality of encapsulated spheres dispersed throughout the heat sink, each encapsulated sphere comprising a solid-to-liquid phase-change material surrounded by a metal shell.

2. The heat sink of claim 1, wherein the solid-to-liquid phase-change material is a water-insoluble phase-change material.

3. The heat sink of claim 1, wherein metal shell comprises copper.

4. The heat sink of claim 1, wherein the solid-to-liquid phase-change material is a paraffin, a fatty acid, a sugar alcohol, or a combination thereof.

5. The heat sink of claim 1, wherein the heat sink is arranged on a heat-generating electronic device.

6. The heat sink of claim 1, wherein the heat sink is formed by electroforming.

7. The heat sink of claim 1, wherein the heat sink is formed by electroplating.

8. A heat-absorbing structure comprising:
a structural matrix comprising a first metal;
a plurality of voids arranged in the structural matrix; and
a phase-change material arranged in the plurality of voids, the phase-change material comprising a second metal.

9. The heat-absorbing structure of claim 8, wherein the heat-absorbing structure is part of a hypersonic vehicle.

10. The heat-absorbing structure of claim 8, wherein the first metal is nickel, chromium, iron, molybdenum, niobium, tantalum, cobalt, manganese, copper, aluminum, titanium, or any combination thereof.

11. The heat-absorbing structure of claim 8, wherein the structural matrix further comprises silicon, carbon, phosphorus, boron, or a combination thereof.

12. The heat-absorbing structure of claim 8, wherein the second metal has a lower temperature of melting than the first metal.

13. A method of making a heat sink, the method comprising:
forming spheres of a phase-change material, the phase-change material comprising a solid-to-liquid phase-change material;
adding the spheres to a metal solution to form metal encapsulated spheres within the metal solution, the metal encapsulated spheres comprising metal shells around the phase-change material; and
using the metal solution comprising the metal encapsulated spheres to form the heat sink.

14. The method of claim 13, wherein using the metal solution comprising the metal encapsulated spheres comprises electroplating.

15. The method of claim 13, wherein using the metal solution comprising the metal encapsulated spheres comprises electroforming.

16. The method of claim 13, wherein the solid-to-liquid phase-change material is water-insoluble phase-change material.

17. The metal of claim 13, wherein the metal shells comprise copper.

18. The method of claim 13, wherein the solid-to-liquid phase-change material is a paraffin, a fatty acid, a sugar alcohol, or a combination thereof.

19. The method of claim 13, wherein using the metal solution comprising the metal encapsulated spheres comprises depositing the metal solution comprising the metal encapsulated spheres as a layer onto a heat-generating electronic device.

20. The method of claim 13, wherein the metal solution comprises copper.
